(19) United States
(12) Patent Application Publication
(10) Pub. No.: US 2006/0190198 A1
(43) Pub. Date: Aug. 24, 2006

(54) Measurement/acquisition system for electric information

(76) Inventors: Tadashi Ishi, Kanagawa (JP); Katsuaki Saito, Kanagawa (JP)

Correspondence Address: ANDERSON, KILL & OLICK, P.C., 1251 AVENUE OF THE AMERICAS, NEW YORK,, NY, 10020-1182, US

(21) Appl. No.: 11/062,250

(22) Filed: Feb. 18, 2005

(51) Int. Cl. G01R 21/00; G01R 21/06

(52) U.S. Cl. 702/60

(57) ABSTRACT

An electric-information measurement/acquisition system comprising a sensor unit, a measurement unit, and an acquisition unit. The sensor unit includes sensors for detecting properties such as the voltage, current, temperature, and moisture,. The measurement unit includes: an A/D conversion unit for performing A/D conversion of the properties thus obtained at a predetermined first cycle; a first computing unit for performing computation at the predetermined first cycle and a predetermined second cycle so as to obtain intermediate data including the accumulated values of the averages of the properties including power-consumption data; and a transmission/reception unit for transmitting the intermediate data according to a request from the acquisition unit at a predetermined third cycle. The acquisition unit performs computation processing and correction processing for the intermediate data obtained from the multiple measurement units, thereby obtaining the properties thereof in a final format.

### TECHNICAL FIELD OF THE INVENTION

The present invention relates to a measurement/acquisition system for acquiring the properties of multiple apparatuses regarding power consumption, and particularly to a measurement/acquisition system for acquiring individual electric information from multiple electric apparatuses by measuring the aforementioned properties.

### DESCRIPTION OF THE RELATED ART

In all fields, facilities of all types are put under an obligation to promote power saving or effective use of electric power giving consideration to the global environmental problems. This requires monitoring of the power consumption of plants, shops, and so forth. However, measurement of overall power consumption of the plant alone is insufficient for analyzing the current state. Accordingly, there is the need to measure power consumption of individual apparatuses or individual systems over time so as to analyze the history thereof. That is to say, this requires a system for measuring power consumption of the individual apparatuses or systems, and centrally acquiring the data thereof.

Furthermore, at the same time of monitoring of power consumption of the individual apparatuses or systems, the voltage and the current are preferably measured and acquired, in addition to the data of power consumption. In some cases, the temperature and moisture are preferably measured and acquired around each apparatus, as well.

With conventional measurement of the voltage, current, and power consumption, the voltage is converted into a low-voltage signal by a PT(Potential Transformer), and the current is converted into a low-current signal by a CT (Current Transformer). The product of both values are computed in an analog manner or a digital manner, thereby obtaining power consumption. A pulse signal is then transmitted corresponding to the power consumption thus obtained, and the pulse signal is accumulated so as to calculate average power consumption over a predetermined increment of time.

With a conventional configuration wherein a host device centrally acquires the data of the average power consumption of the aforementioned individual apparatuses and so forth, a watt-hour meter or the like provided for each apparatus transmits a pulse train to a transmission line; the pulse train having pulses of which the number is determined corresponding to the power consumption at a predetermined pulse-creating rate (e.g., 2,000 pulses/hWh). The aforementioned host device counts the number of the pulses so as to obtain power consumption every predetermined period of time, or average power consumption.

However, with such a configuration, each apparatus requires a transmission line, leading to difficulty in multiplexing.

Furthermore, with a configuration wherein a personal computer serves as the aforementioned host device for acquiring and analyzing the aforementioned pulse trains from the aforementioned transmission lines via a network, the personal computer receives the aforementioned pulse trains in the form of an excessively great amount of raw data for analysis in the final stage, leading to ineffective operation of the interfaces therebetween.

Furthermore, with an arrangement employing commercial-grade watt-hour meters, such watt-hour meters or the like are expensive and dedicated for each apparatus corresponding to the kind of the power supply mode, such as 50 Hz/60 Hz, three-phase/single-phase/multi-phase, 200 V/100 V, and so forth, and further require maintenance, leading to increased costs.

Furthermore, a conventional arrangement such as is taught in Japanese Unexamined Patent Application Publication No. 2001-257676 and Japanese Unexamined Patent Application Publication No. 2001-041985 for acquiring the data of temperature and moisture around each apparatus, in addition to the data of the power consumption, requires a new measurement/acquisition system for the data of temperature and moisture, leading to more serious problems.

### SUMMARY OF THE INVENTION

The present invention is a measurement/acquisition system for securing measurement data of the properties of electric equipment regarding power consumption such as electric power, voltage, and current, and/or temperature and moisture, for each of a great number of apparatuses, as multiplexed data in a compact format with high cost performance, and providing only the information necessary for analysis by a host device.

The present invention has a function for allowing the user to employ general-use and standard hardware regardless of the kind of the power-supply mode determined for each apparatus, or regardless of whether or not measurement of the temperature and moisture is made, as well as a function for automatically updating the corresponding parameters used in software.

The electric-information measurement/acquisition system of the present invention comprises: sensor unit(s) for detecting the properties of multiple apparatuses with regard to power consumption in the form of analog signals; measurement unit(s) for converting the analog signals to digital signals, and performing first computation so as to obtain intermediate data; and an acquisition unit for acquiring the intermediate data from the plurality of measurement units, with the sensor unit detecting the voltage and current corresponding to power consumption of each of the apparatuses in the form of analog voltage signals vv and vi proportional to the voltage and current, and with the measurement unit including: an A/D conversion unit for converting the analog voltage signals vv and vi into output signals VV and VI, respectively, in the form of digital signals, at a predetermined first cycle; a first computing unit for computing the squares of the output signals VV and VI, and computing the product of VV and VI, so as to obtain VV2, VI2, and power consumption P, computing the averages thereof at a predetermined second cycle, and extracting the square roots of the averages of VV2 and VI2; a first accumulation unit for accumulating the values, and storing intermediate data formed of the accumulated values thus obtained and the number of accumulations N; a transmission/reception unit for transmitting the intermediate data to the acquisition unit according to a transmission request signal from the acquisition unit; and resetting means for removing the intermediate data stored in the first accumulation unit after transmission of the intermediate data, and with the acquisition unit including: a transmission/reception control unit for transmitting an intermediate-data transmission request signal to each of the multiple measurement units at a predetermined third cycle, and receiving the intermediate data; a second computing unit for dividing each of the accumulated values by the number of accumulations N based upon the intermediate data so as to calculate and correct the averages (average voltage, average current, and average power consumption) in a period of time between the previous and current transmission request signals; and a second accumulation unit for storing the computation results.

More preferably the sensor unit has functions for detecting the temperature and moisture with regard to the apparatuses in the form of analog signals vt and vh proportional to the temperature and moisture, with the measurement unit further including: an A/D conversion unit for obtaining the output signals VT and VH in the form of digital signals corresponding to the analog voltage signals vt and vh at the predetermined first cycle; and a first computing unit for computing the averages of the output signals VT and VH, and accumulating each of the averages thus obtained, so as to obtain the accumulated values thereof, at the predetermined second cycle, and with the intermediate data further containing the accumulated values of averages of VT and VH.

The aforementioned first computing unit in the electric information gathering system of the present invention computes information in a predetermined period of time of 1.25 msec or 1/integral number of it and the aforementioned second computing unit computes information in a predetermined period of time of 80 msec (in a case employing a 50-Hz system), or the aforementioned first computing unit's predetermined period of time of 1/960 sec or 1/integral number of it, and the aforementioned second computing unit's predetermined period of time of 1/15 sec (in a case employing a 60-Hz system).

Moreover, the measurement unit of the present invention further includes means which allow the user to make settings of the mode thereof including setting of the power-supply mode (50 Hz/60 Hz, three-phase/single-phase/multi-phase, and/or 200 V/100 V) and/or setting of the temperature/moisture measurement mode for each apparatus.

Moreover, data transmission between the acquisition unit and the transmission/reception unit of the measurement unit should preferably be performed by serial transmission.

[Advantages]

The most preferred electric-power measurement system of the present invention is a hierarchical structure formed of multiple apparatuses, multiple sensor units, multiple measurement units, and an acquisition unit, in the order from the bottom to the top. Each measurement unit should serve as a general-purpose board, as well as to allow the user to connect the multiple measurement units to the acquisition unit through a general-purpose transmission interface. Such a configuration enables effective data acquisition without mal-distribution of load, as well as allowing the user to easily set the mode including determination of the measurement mode immediately corresponding to the power-supply mode in the field at the time of installing of the sensor unit and the measurement unit (general-purpose board), update thereof, and maintenance thereof.

### BRIEF DESCRIPTION OF THE DRAWINGS

[FIG. 1]

FIG. 1 shows a first embodiment according to the present invention.
[FIG. 2]

FIG. 2 shows a second embodiment according to the present invention.

### DETAILED DESCRIPTION OF THE PREFERRED EMBODIMENTS

### First Embodiment

An example of a first embodiment of the present invention, which has two apparatuses (apparatuses 1 and 2) wherein power consumption is to be monitored, is hereafter described with reference to FIG. 1.

According to the present invention, a sensor unit includes: a voltage sensor for detecting the voltage of a common power supply; current sensors 1 and 2 for detecting current consumption of the apparatuses 1 and 2; a temperature sensor for detecting the temperature around the apparatus; and a moisture sensor for detecting the moisture therearound. These sensors output analog voltages vv, vi1, vi2, vt, and vh, respectively.

Furthermore, a measurement unit 1 includes a CPU. A/D converting units 1 through 5 of the measurement unit 1 convert the aforementioned analog signals into digital signals according to enable signals ENABLE from the aforementioned CPU, thereby outputting a voltage signal VV, current signals VI1 and VI2, a temperature signal VT, and a moisture signal VH. A first computing unit of the CPU squares VV, VI1, VI2, and computes the product of VV and VI1, and the product of VV and VI2 so as to obtain power consumption P1 and P2. The square values VV, VI1, and VI2, and the values P1, P2, VT, and VH, are added to the previous sums, thereby computing the new sums.

The computation from the step for digital conversion up to the step for computing the new sums is performed once every first predetermined period of time which is 1.25 msec, or a period of time which is obtained by dividing 1.25 msec by an integer.

Furthermore, the aforementioned first computing unit computes the averages of the aforementioned sums once every second predetermined period of time which is 80 msec (in a case of employing a 50 Hz system), or once every 1/960 sec (in a case of employing a 60 Hz system). Furthermore, the first computing unit extracts the square roots of the averages of the square of VV, the square of VI1, and the square of VI2.

Subsequently, a first accumulation unit of the CPU adds these values thus obtained to the corresponding previous accumulated values in the predetermined second period of time, thereby obtaining the new accumulated values. The first accumulation unit stores the accumulated values and the number of accumulations N in the form of intermediate data.

While description has been made regarding an example of the measurement unit 1 having the simplest configuration for monitoring the single-phase common power supply, the two apparatuses, the single temperature sensor and moisture sensor, in general, the measurement unit monitors apparatuses with various power-supply modes, which requires setting of the mode thereof.

More specifically, the user must specify the number of the apparatuses which are to be monitored, and the range of current consumption for each apparatus, in addition to the frequency of the common power-supply system (50 Hz or 60 Hz), the power-supply method (single phase three wire 120/240V; single phase three wire 100/200V; three phase three wire 200V; three phase four wire 120/208V wye-connected; three phase four wire 120/240 V delta-connected)and setting whether or not the temperature and moisture are to be measured. With the present first embodiment, these values are specified by hardware means, i.e., by wiring at the time of installing the sensor unit for each apparatus, following which the user can make or update setting of the mode of the measurement unit 1 using dip switches included in the measurement unit 1, thereby enabling the CPU to read out the information in operation with ease.

In other words, the measurement unit has a standard hardware configuration serving as a single kind of general-purpose board including sixteen A/D converters and the sixteen corresponding channels, for example. In operation, setting of the mode thereof is made simply by setting the corresponding dip switches at the same time of wiring for the sensor units corresponding to the various power-supply modes in the field. That is to say, with the present embodiment, individual settings of the measurement unit different one from another can be performed with a single kind of general-purpose board according to the simple and standard procedure.

Referring to FIG. 1, again, the intermediate data stored in the aforementioned first accumulation unit is transmitted to an acquisition unit according to a transmission request signal from the acquisition unit. More specifically, data transmission/reception is performed between a transmission/reception unit of the measurement unit 1, serving as a slave, and a transmission/reception control unit included in the CPU of the acquisition unit, serving as a master, through the RS485 interface having functions of serial transmission. Note that the transmission request signal is output once every predetermined third period of time, e.g., once every one minute.

The measurement unit 1 resets the aforementioned accumulated values and the number of accumulations N immediately after transmission of the aforementioned intermediate data using a RESET signal. Then, the measurement unit 1 accumulates and stores the intermediate data until reception of the next transmission request from the acquisition unit.

Upon the acquisition unit receiving the intermediate data, a second computing unit of the acquisition unit divides, by the number of accumulations N, the accumulated values of the square roots of the averages of the squares of the voltage VV and current VI, and the averages of the power consumption P, the temperature VT, and the moisture VH, thereby obtaining the averages for the predetermined third period of time. These averages thus obtained are converted into values in the form of practical units, and are corrected for the measurement unit 1 or for each apparatus in the final stage, following which these values thus obtained are stored in a second accumulation unit.

At the time of conversion of the measurement values into values in the form of practical units, the acquisition unit requires the aforementioned mode-setting information and the corresponding conversion information such as the range of current consumption and so forth, for example. With the present embodiment, the CPU of the measurement unit reads out the state of the aforementioned dip switches, and transmits the conversion information thus obtained, to the acquisition unit, with ease by software means.

While description has been made regarding an arrangement wherein the voltage and current are obtained in the form of the square roots of the averages of the squares thereof, an arrangement may be made wherein the measurement unit computes the values of the voltage and current in the form of the averages of the absolute values thereof.

Furthermore, an arrangement may be made wherein the measurement unit of the aforementioned second computing unit performs part of computation, instead of the acquisition unit thereof.

The information stored in the aforementioned second accumulation unit may be transmitted to an analysis unit (not shown) via a dedicated line, an LAN line, or a public line, so as to be used for analyzing power consumption of the overall plant or the overall system including multiple plants. [0033]

The acquisition unit serving as a master controls the measurement unit serving as a slave through the RS485 interface having a function for serial transmission. Thus, an arrangement may be made wherein a measurement unit 2 having the same functions as with the measurement unit 1 is connected to the same serial transmission path as shown in FIG. 1, thereby allowing acquisition of the intermediate data regarding another apparatus group. Furthermore, such configuration allows an expanded arrangement up to 30 measurement units, for example.

As described above, with the present embodiment, the intermediate data which is transmitted and received between the measurement unit and the acquisition unit is formed in a standard format, thereby allowing the user to easily expand, update, and maintain the power-consumption measurement system according to the present invention.

Now, description will be made regarding the data measurement rate of the measurement unit according to the present embodiment. Let us say that each measurement unit includes sixteen AID converters having a function for outputting a 2-byte signal. With such a configuration, the aforementioned first computing unit computes data of 2 bytes×16=32 bytes once every predetermined first period of time which is 1.25 msec (i.e., 800 Hz), so as to obtain data of 4 bytes×an integer (an integer of 16 to 30, depending upon the mode of the measurement unit), i.e., a maximum of 120-byte data.

Furthermore, the data thus obtained is subjected to computation processing, and the number of accumulations N (4 byte) is appended, once every predetermined second period of time which is 80 msec (i.e., 12.5 Hz), whereby a maximum of 124-byte data is obtained.

Furthermore, the data thus obtained is transmitted to the acquisition unit once every predetermined third period of time which is one minute.

That is to say, the first computation unit outputs the data at data-output rates of 32 bytes×800 Hz=25600 Bps, 120 bytes×12.5 Hz=1550 Bps, and 124 bytes×( 1/60) Hz=2 Bps, in those steps.

### Second Embodiment

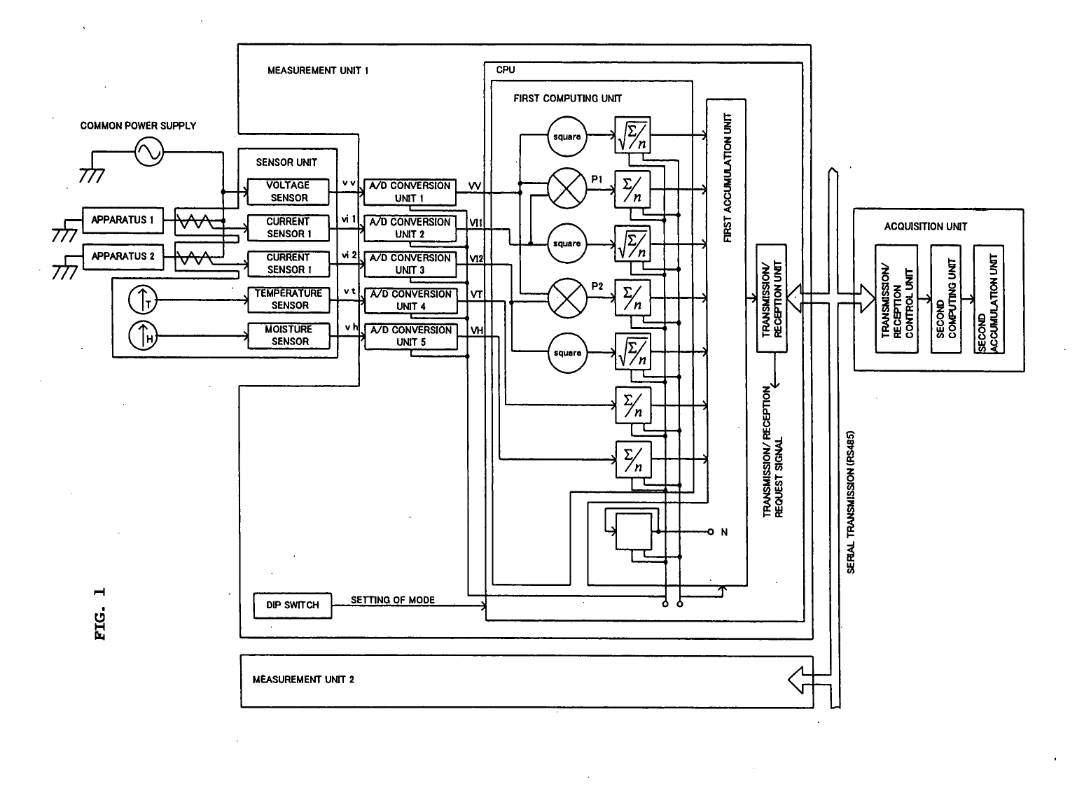

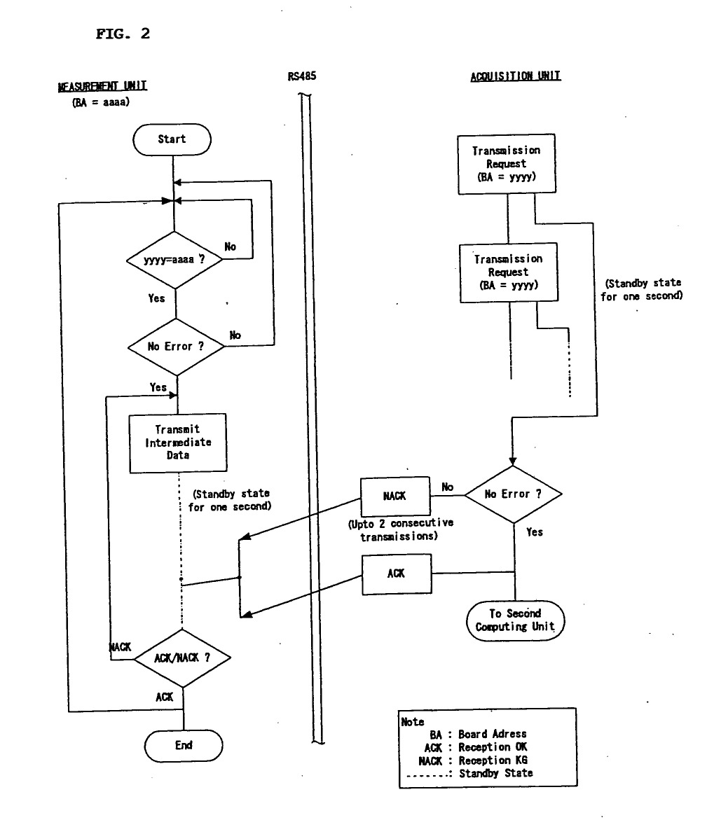

The following description involves data transmission/reception between the measurement unit and the acquisition unit through serial transmission with reference to FIG. 2. [0037]

The acquisition unit transmits a transmission request with a unique address yyyy for transmission of the intermediate data, to each of the multiple measurement units through the RS485. The flow proceeds to the step for the next transmission request, as well as awaiting the response corresponding to the aforementioned request which has been transmitted.

Each measurement unit monitors the RS485. In the event that the measurement unit detects the request with an address not matching the board address BA of aaaa of itself, the measurement unit maintains the standby state (NA). Only in the event of detection of the received address matching the board address BA of aaaa of itself, first, the measurement unit performs an error check with regard to the information packet thereof.

In a case of detection of error, the measurement unit ignores the request, and maintains the standby state (NA). Only in a case of detection of no error, the measurement unit transmits the intermediate data in the predetermined format containing the board address BA of itself, following which the measurement unit enters the standby state.

Upon the acquisition unit receiving the response within a predetermined timeout period (e.g., 1 second), the acquisition unit performs error check with regard to the information packet thereof. In a case of detection of error, the acquisition unit transmits a NACK signal to the aforementioned measurement unit with the board address BA of aaaa (note that such transmission is limited to two times, for example). In a case of detection of no error, the acquisition unit transmits the obtained intermediate data and the board address BA to the second computing unit, as well as transmitting an ACK signal to the aforementioned measurement unit with the board address BA of aaaa.

Upon receiving the aforementioned ACK signal or NACK signal with the board address of itself, in a case of reception of the ACK signal, this measurement step ends in the normal state, and the flow returns to the standby state in the initial stage. On the other hand, in a case of reception of the NACK signal, the measurement unit transmits the intermediate data again.

When exceeding the timeout period, or in a case of three or more consecutive receptions of the NACK signal, the acquisition unit enters an error routine (not shown) for handling the abnormal state the detailed description of which is omitted in this specification.

What is claimed is:

1. A measurement/acquisition system for electric information comprising:
at least one sensor unit for detecting analog signals from a plurality of apparatuses representing selected properties with regard to power consumption;
at least one measurement unit for converting said analog signals to digital signals, and performing first computation so as to obtain intermediate data; and
an acquisition unit for acquiring said intermediate data from said measurement unit(s);
wherein said sensor unit detects the voltage and current corresponding to power consumption of each of said apparatuses in the form of analog voltage signals vv and vi proportional to said voltage and current,
and wherein said measurement unit includes
an A/D conversion unit for converting said analog voltage signals vv and vi into output signals VV and VI, respectively, in the form of digital signals, at a predetermined first cycle,
a first computing unit for computing the squares of said output signals VV and VI, and computing the product of VV and VI, so as to obtain VV2, VI2, and power consumption P, computing the averages thereof at a predetermined second cycle, and extracting the square roots of the averages of VV2 and VI2,
a first accumulation unit for accumulating said values, and storing intermediate data formed of the accumulated values thus obtained and the number of accumulations N,
a transmission/reception unit for transmitting said intermediate data to said acquisition unit according to a transmission request signal from said acquisition unit, and
resetting means for removing said intermediate data stored in said first accumulation unit after transmission of said intermediate data,
and wherein said acquisition unit includes
a transmission/reception control unit for transmitting an intermediate-data transmission request signal to each of said plurality of measurement units at a predetermined third cycle, and receiving said intermediate data,
a second computing unit for dividing each of said accumulated values by said number of accumulations N based upon the said intermediate data so as to calculate and correct the averages (average voltage, average current, and average power consumption) in a period of time between the previous and current transmission request signals, and
a second accumulation unit for storing the computation results.

2. A measurement/acquisition system for electric information according to claim 1, wherein said sensor unit has functions for detecting the temperature and moisture with regard to said apparatuses in the form of analog signals vt and vh proportional to said temperature and moisture;
and wherein said measurement unit further includes
an A/D conversion unit for obtaining the output signals VT and VH in the form of digital signals corresponding to said analog voltage signals vt and vh at said predetermined first cycle, and
a first computing unit for computing the averages of said output signals VT and VH, and accumulating each of said averages thus obtained, so as to obtain the accumulated values thereof, at said predetermined second cycle;
and wherein said intermediate data further contains said accumulated values of averages of VT and VH.

3. A measurement/acquisition system for electric information according to claim 1 wherein said predetermined first cycle is 1.25 msec cycle, or a cycle obtained by dividing 1.25 msec by an integer;
and wherein said predetermined second cycle is an 80 msec cycle (in a case wherein said apparatuses employ a 50-Hz power system), or a 1/960 sec cycle (in a case wherein said apparatuses employ a 60-Hz power system);
and wherein said predetermined third cycle is no shorter than said predetermined second cycle.

4. A measurement/acquisition system for electric information according to claim 2 wherein said predetermined first cycle is a 1.25 msec cycle, or a cycle obtained by dividing 1.25 msec by an integer;
and wherein said predetermined second cycle is an 80 msec cycle (in a case wherein said apparatuses employ a 50-Hz power system), or a 1/960 sec cycle (in a case wherein said apparatuses employ a 60-Hz power system);
and wherein said predetermined third cycle is no shorter than said predetermined second cycle.

5. A measurement/acquisition system for electric information according to claim 1 wherein said measurement unit further includes means which allow the user to perform settings of the mode thereof including setting of the power-supply mode (single phase, three wire, 120/240V; single phase, three wire, 100/200V; three phase, three wire 200V; three phase, four wire 120/208V wye-connected; three phase four wire 120/240 V delta-connected) and/or setting of the temperature/moisture measurement mode for each apparatus.

6. A measurement/acquisition system for electric information according to claim 2 wherein said measurement unit further includes means which allow the user to perform settings of the mode thereof including setting of the power-supply mode (single phase, three wire, 120/240V; single phase, three wire, 100/200V; three phase, three wire 200V; three phase, four wire, 120/208V wye-connected; three phase, four wire 120/240 V delta-connected) and/or setting of the temperature/moisture measurement mode for each apparatus.

7. A measurement/acquisition system for electric information according to claim 1, wherein data transmission between said acquisition unit and said transmission/reception unit of said measurement unit is performed by serial transmission.

8. A measurement/acquisition system for electric information according to claim 2, wherein data transmission between said acquisition unit and said transmission/reception unit of said measurement unit is performed by serial transmission.

9. A measurement/acquisition system for electric information according to claim 3, wherein data transmission between said acquisition unit and said transmission/reception unit of said measurement unit is performed by serial transmission.

10. A measurement/acquisition system for electric information according to claim 4, wherein data transmission between said acquisition unit and said transmission/reception unit of said measurement unit is performed by serial transmission.
